(19) United States
(12) Patent Application Publication
(10) Pub. No.: US 2025/0266233 A1
(43) Pub. Date: Aug. 21, 2025

(54) ELECTROSTATIC CHUCK FOR ION BEAM DEPOSITION SYSTEMS

(71) Applicant: VEECO INSTRUMENTS INC., Plainview, NY (US)

(72) Inventors: Frank CERIO, Plainview, NY (US); Rutvik MEHTA, Plainview, NY (US)

(21) Appl. No.: 19/052,193

(22) Filed: Feb. 12, 2025

Related U.S. Application Data
(60) Provisional application No. 63/555,557, filed on Feb. 20, 2024.

(51) Int. Cl. H01J 37/20; H01J 37/317

(52) U.S. Cl. CPC H01J 37/20; H01J 37/3178; H01J 2237/2007

(57) ABSTRACT

An electrostatic chuck for ion beam deposition systems having an assist beam and that can be operated at elevated temperature. The electrostatic chuck includes or is operably connected to a power source capable of outputting at least 1 milliAmp of current, to provide a nominal voltage of at least 150V (+150V or −150V) and a total voltage differential, whether for a monopolar source or across multiple power sources, of at least 300V. The power source is isolated or floating with respect to ground.

### CROSS REFERENCE

This application claims priority to U.S. provisional application No. 63/555,557 filed Feb. 20, 2024, the entire disclosure of which is incorporated herein by reference for all purposes.

### BACKGROUND

Ion beam deposition (IBD) is one of many methods suitable for forming metallic films, such as for semiconductor processing; the other methods include (but are not limited to) plasma vapor deposition (PVD), chemical vapor deposition (CVD), and molecular beam epitaxy (MBE). MBE is useful for depositing layers at very low energy, which can produce pseudo epitaxial layers. PVD is useful for depositing layers at a higher energy, which can produce layers that have, e.g., good electrical conductivity capabilities. IBD is useful for depositing layers at still higher energy and reduced pressures and with control of deposition geometry, which can produce layers with higher crystallinity and with controlled microstructures. Some IBD systems combine both material deposition and etch (or assist).

For IBD, the substrate on which the layer is being formed is typically held by a clamp or chuck; these clamps or chucks are commonly either mechanical or electrostatic. The selection of the clamp or chuck is highly dependent on the deposition system and the processing conditions.

### SUMMARY

The present disclosure is directed to electrostatic chucks for ion deposition systems having both deposition and etch (assist) capabilities, with available heating of the substrate to an elevated temperature of at least 250° C. during processing. The support surface of the chuck is a high temperature resistant material, such as a high temperature ceramic.

The electrostatic chuck includes or is operably connected to a power source capable of outputting at least 1 mA of current, to provide a nominal voltage of at least 150V (+150V or −150V) and a total voltage differential, whether for a monopolar source or across multiple power sources, of at least 300V.

A particular embodiment described herein is an AlN heated electrostatic chuck powered with a DC power supply capable of driving high a voltage (up to about 1000V) at high currents (e.g., up to 100 mA), with the output isolated or floating with respect to ground.

Another particular embodiment described herein is an AlN heated electrostatic chuck powered with a power supply that includes two DC power sources capable of driving high a voltage (up to about 1000V) at high currents (e.g., up to 100 mA) with both outputs isolated or floating with respect to ground.

Yet another particular embodiment described herein is an electrostatic chuck for holding a substrate, the chuck having a support assembly having two electrodes therein and an electrically insulating support surface for receiving the substrate, a heating element operably connected to the support surface, and a high current, high voltage power supply having two outputs operably connected to the electrodes, with each of the power supply outlets isolated or floating with respect to ground. The high current, high voltage power supply can be configured to provide 1 to 100 mA.

Another particular embodiment of an electrostatic chuck for holding a substrate has a high current, high voltage power supply for operating the electrostatic chuck, the power supplying having two outlets isolated or floating with respect to ground, a support assembly with a heating element for heating an electrically insulating support surface of the support assembly, and at least two electrodes within the support assembly and electrically connected to the outlets of the power supply for charging the electrodes to electrostatically hold the substrate to the electrostatic chuck.

Any of the electrostatic chucks can be part of a system, such as a deposition system for applying material onto a substrate.

One particular embodiment of a system has an ion deposition beam system, an assist ion system, and an electrostatic chuck having two electrodes within a heated support assembly, the electrodes electrically connected to outlets of a high current, high voltage power supply for charging the electrodes to electrostatically hold a substrate to the electrostatic chuck, wherein the power supply outlets are isolated or floating with respect to ground

Also described herein is a method of holding a substrate in a process chamber. The method includes providing an electrostatic chuck having a heated support assembly with an electrically insulative support surface in the process chamber, the support assembly having two electrodes therein electrically connected to outlets of a power supply for charging the electrodes, the outlets isolated or floating with respect to ground; placing a substrate on the support surface; and applying a current of at least 1 milliAmp via the power supply to the at least two electrodes to produce a voltage differential of at least 300V. Heating the substrate may be to a temperature of at least 250° C.

Another method of holding a substrate in a process chamber includes providing an electrostatic chuck comprising a heated support assembly having an electrically insulative support surface in the process chamber, the support assembly having two electrodes therein electrically connected to outlets of a power supply for charging the electrodes, the outlets isolated or floating with respect to ground; placing a substrate on the support surface; and applying a current of at least 1 milliAmp via the power supply to the at least two electrodes to produce a voltage differential of at least 150V.

Yet another method includes providing an electrostatic chuck comprising a support assembly having an insulative support surface in the process chamber, the support assembly having two electrodes therein electrically connected to outlets of a high current, high voltage power supply for charging the electrodes, the outlets isolated or floating with respect to ground; placing a substrate on the support surface; and electrostatically holding the substrate to the support surface by applying power to the electrodes with the power supply in an isolated or floating state.

This Summary is provided to introduce a selection of concepts in a simplified form that are further described below in the Detailed Description. This Summary is not intended to identify key or essential features of the claimed subject matter, nor is it intended to be used to limit the scope of the claimed subject matter. These and various other features and advantages will be apparent from a reading of the following Detailed Description.

### BRIEF DESCRIPTION OF THE DRAWING

FIG. 1 is a schematic side view of an ion beam deposition system with an assist ion beam system.

FIG. 2 is a schematic rendering of a mechanical chuck.

FIG. 3 is a schematic diagram of a generic electrostatic chuck with a substrate.

FIG. 4 is a schematic rendering of an ion beam deposition system with a first example of an electrostatic chuck.

FIG. 5 is a schematic rendering of an ion beam deposition system with a second example of an electrostatic chuck.

FIG. 6 is a schematic rendering of an ion beam deposition system with another example of an electrostatic chuck.

FIG. 7 is a schematic rendering of an ion beam deposition system with another example of an electrostatic chuck.

FIG. 8 is a stepwise method for forming a thin layer metal film in an ion beam deposition system with assist.

### DETAILED DESCRIPTION

Semiconductor devices are used extensively, from computers and printers, to cars, to appliances, and even in toys. The manufacturing process for a semiconductor chip involves many steps, typically starting with a bare semiconductor substrate, or wafer. The semiconductor substrate material historically has been silicon, but materials now include silicide(s), nitride(s), oxide(s), metal(s) including alloys, and ceramic(s).

During processing, both in transfer between various pieces of machinery and during the actual processing step, the substrate must be held in place; this is typically done using a chuck. There are different types of chucks, including a mechanical chuck (which uses pins to hold the substrate in place), a vacuum chuck (which uses a vacuum force to hold the substrate in place), or an electrostatic chuck (which uses electrostatics to hold the substrate in place). As indicated above, this disclosure is directed to electrostatic chucks.

In the following description, reference is made to the accompanying drawing that forms a part hereof and in which is shown by way of illustration at least one specific implementation. The following description provides additional specific implementations. It is to be understood that other implementations are contemplated and may be made without departing from the scope or spirit of the present disclosure. The following detailed description, therefore, is not to be taken in a limiting sense. While the present disclosure is not so limited, an appreciation of various aspects of the disclosure will be gained through a discussion of the examples, including the figures, provided below. In some instances, a reference numeral may have an associated sub-label consisting of a lower-case letter to denote one of multiple similar components. When reference is made to a reference numeral without specification of a sub-label, the reference is intended to refer to all such multiple similar components.

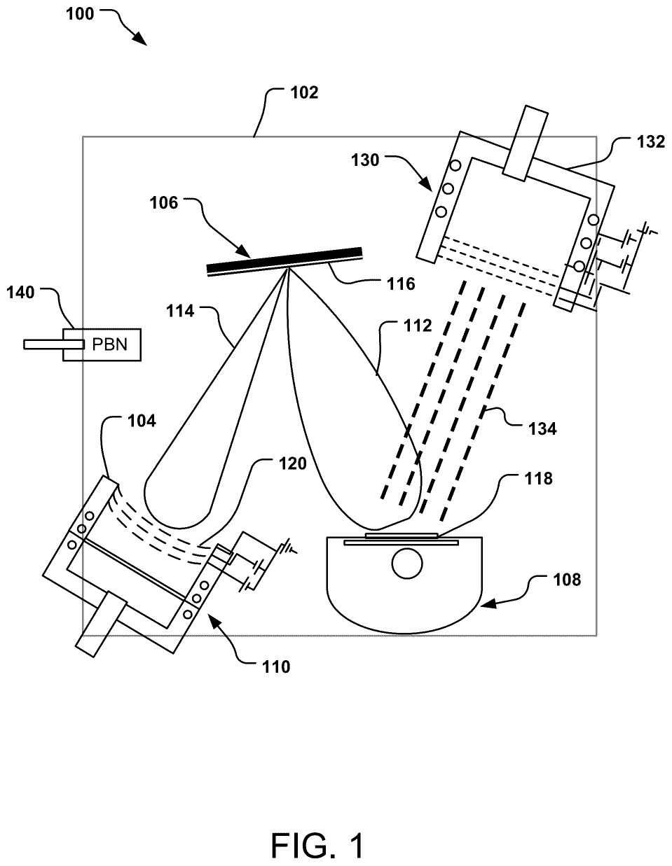

Turning to the figures, FIG. 1 illustrates a system 100 according to the present disclosure, the system 100 including an ion beam deposition (IBD) system and an assist ion or ion beam etch system. The system 100 also has one or more ion beam neutralizers and their associated gas distribution systems. The system 100 may have an apparatus for introduction of reactive gas species into the process chamber.

The system 100 includes a chamber 102 having therein a, ion beam deposition system 110 that includes an ion beam source 104, and also a target assembly 106, and a substrate assembly 108 for supporting a substrate 118 that may be formed of, for example, one or multiple layers of silicide(s), nitride(s), oxide(s), metal(s) including alloys, or ceramic(s). Incorporated into the substrate assembly 108 is a chuck to hold the substrate 118.

The ion beam source 104 generates an ion beam 114, which can include a plurality of ion beamlets targeted or directed toward the target assembly 106, which includes at least one target 116 composed of the material to be deposited. The system 100 may include one or more grids 120 proximate the ion beam source 104 for directing the ion beam 114 from the ion beam source 104 to the target 116. A source gas is used in the ion source 104 to help generate the ion beam 114.

Also present in the system 100 may be a heat source (not shown), such as heating element(s) present within the chamber 102 or heating element(s) as part of or connected to the substrate assembly 108.

The ion beam 114, upon striking the target 116, generates a sputter plume 112 of material from the target 116. The ion beam 114 strikes the target 116 at such an angle so that the sputter plume 112 generated from the target 116 travels towards the substrate 118. The sputter plume 112 may be made more or less concentrated so that its resulting deposition of material on the substrate 118 is more effectively distributed over a particular area of the substrate 118.

The system 100 also includes an assist ion beam system 130 that provides a source of ions that bombards the substrate 118 so that material on the substrate 118 is removed or modified. The assist ion beam system 130 may be referred to an ion beam etching system, or the like.

The assist ion beam system 130 includes an ion beam source 132 that generates an assist ion beam 134, that can include a plurality of ion beamlets, targeted or directed toward the substrate assembly 108, particularly toward the substrate 118. The assist ion beam 134 controls the net amount of material deposited on the substrate 118. In some implementations, the assist ion beam 134 modifies the material that is being deposited by the sputter plume 112.

The target assembly 106 is positioned so that the ion beam 114 strikes the target 116 at a predetermined desired angle and also so that the sputter plume 112 strikes the substrate 118 at a predetermined desired angle. Any or all of the ion beam source 104, the target assembly 106 and the substrate assembly 108 may be pivotable, rotatable, movable, etc. Those skilled in the art will appreciate that the relative positions of the sputter plume 112 and the assist ion beam 134 can be such that the deposition angle and the etch angle can be adjusted over a range of angles.

The deposition ion beam system 110 may be, for example, a broad ion beam system, e.g., having a plasma bridge neutralizer (PBN) 140 for generating low energy electrons via the introduction of reactive gases into the chamber 102.

Such a system 100, having an IBD system 110 and an assist ion beam system 130, may be referred to as an ion beam deposition system with assist. When using reactive gases in the process chamber 102 (introduced via various manners), the system 100 may be referred to as a reactive ion beam deposition system.

The system 100, having ion beam deposition with an assist ion beam, can be used to deposit, deposit and modify, and/or deposit and etch, with or without reactive gases, either simultaneously or sequentially or interpedently. By adjusting the net deposition rate of material onto the substrate 118, not only is the thickness of the deposited material controlled, but the physical properties of the deposited material, including microstructure and grain growth, can be controlled. The net deposition can be adjusted, e.g., by adjusting the rate of deposition by the IBD system 110 and the rate of modification by the assist ion beam system 130, by adjusting the net deposition rate of target material onto the substrate 118, by adjusting the rate of reaction between the gas species introduced into the chamber and the material in the target 116 and/or the sputter plume 112, and by the rate of dissociation of the reacted metal compounds to form the desired material.

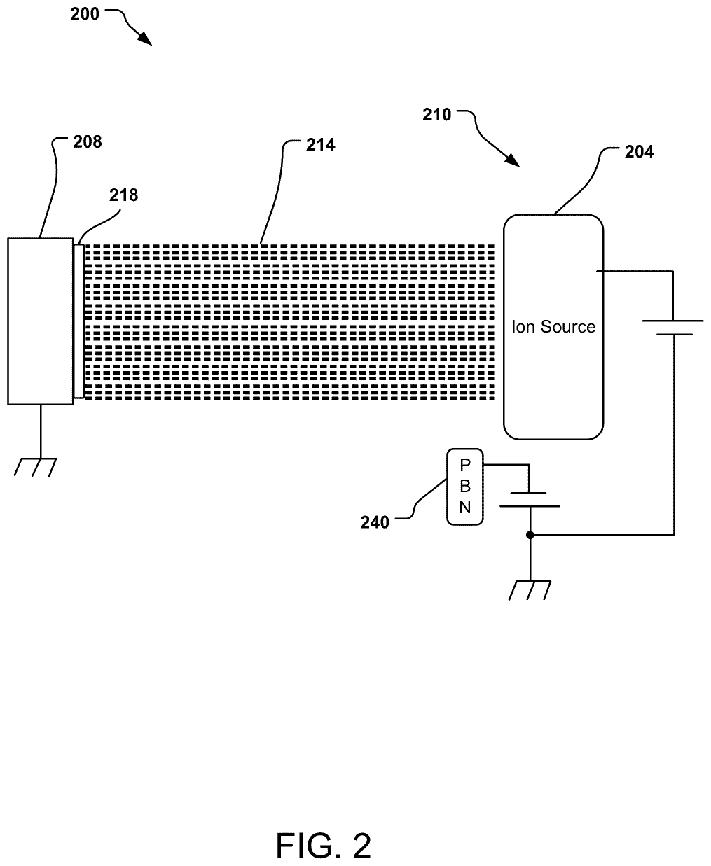

During the processing (e.g., the depositing, depositing and modifying, and/or depositing and etching), the substrate 118 is securely held in or to the substate assembly 108. FIG. 2 provides a simplified schematic of an ion beam deposition system with a generic mechanical chuck holding a substrate.

In FIG. 2, an ion beam deposition system 200 has an ion deposition assembly 210 that includes an ion source 204 and a PBN 240. Each of the ion source 204 and the PBN 240 has a power source (not numbered) which are grounded; although shown connected, the sources may be individually grounded. The ion source 204 produces an ion beam 214 toward a substrate 218 retained on a substrate assembly 208. The particular substrate assembly 208 is a mechanical chuck that is grounded in order to have the ion beam 214 deposit material onto the substrate 218.

Although a mechanical chuck is a good system for retaining the substrate 218 during a deposition process (no arcing is typically observed), a problem with a mechanical chuck is that it may damage the edges of the substrate and prevent deposition on the complete surface of the substrate, including the bevel of the substrate, which is desirable in many applications. Additionally, a mechanical chuck does not readily allow for direct heating of the substrate 218 during the process, as the physical dimensions of the substrate 218 will change with temperature, possibly further damaging the substrate.

As indicated above, this disclosure is directed to electrostatic chucks for ion deposition systems having both deposition and etch (assist) capabilities and heating of the substrate.

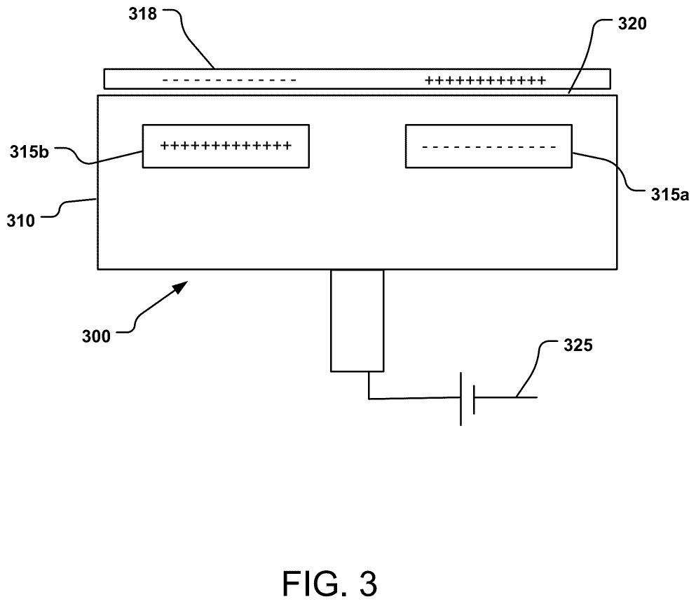

FIG. 3 illustrates an example, generic electrostatic chuck 300. The electrostatic chuck 300 includes a body 310 having at least two electrodes 315a, 315b embedded therein, and a support surface 320 for receiving a semiconductor substrate 318 thereon. The support surface 320 can be any number of materials, depending on the application; for room temperature deposition processes, the support surface 320 is often a dielectric material such as alumina, quartz, sapphire, or polyimide. The support surface 320 may be a layer on the body 310 or the support surface 320 may be integral with the body 310, the body 310 and the support surface 320 being the same material.

The electrostatic chuck 300, particularly the electrodes 315, are connected to outputs of a high-voltage power supply 325 to provide a current, at a voltage, to the electrodes 315.

In use, the substrate 318 is placed on the chuck 300, against the support surface 320. Once the semiconductor substrate 318 is in contact with the chuck 300, the power supply 325 is activated. Activation of the power supply 325 induces a strong electric field in the electrodes 315. For the two-electrode design of FIG. 3, this results in regions of positive and negative charges in the electrodes 315. This also results in induced regions of positive and negative charge in the substrate 318 opposite the chuck electrodes 315 (the charges in the substrate 318 of opposite sign of that of the electrodes 315), resulting in a positive grip pressure due to the opposing charges. The substrate 318 is thus held in place.

The voltage is typically applied to the chuck electrodes 315 via a direct current (DC) but could be via an alternating current (AC).

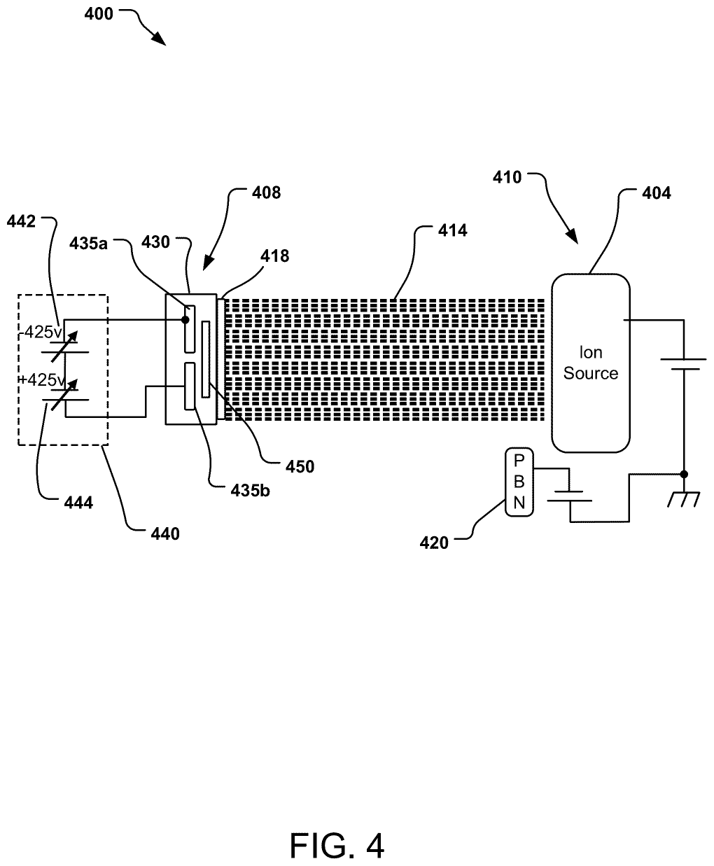

FIGS. 4 through 7 provide specific electrostatic chucks for use with ion deposition systems having both deposition and etch (assist) capabilities and heating of the substrate.

Turning to FIG. 4, a system 400 is shown having an ion beam deposition assembly 410 that includes an ion source 404 and a PBN 420. Each of the ion source 404 and the PBN 420 has a power source (not numbered) which are grounded; although shown connected, the sources may be individually grounded. The ion source 404 produces an ion beam 414 aimed toward a semiconductor substrate 418 retained on a substrate assembly 408 that includes an electrostatic chuck 430. The electrostatic chuck 430 has at least two electrodes 435a, 435b embedded therein, and a support surface for receiving the substrate 418 thereon. The electrostatic chuck 430, particularly the electrodes 435, are connected to a high-voltage, high-current power supply 440 to provide a current, at a voltage, to the electrodes 435. One example of a power supply 440 provides a 1 to 100 milliAmp (mA) current to produce the voltage (e.g., up to about 1000V) to the retain the substrate on the support surface.

Also present in the system 400 is a heating element 450 for heating the substrate 418, e.g., to a temperature of at least 250° C., e.g., 250° C.-650° C. The heating element 450 is shown within the substrate assembly 408 of the system 400 but can be operably connected to the substrate assembly 408. In some embodiments, the heating element 450 may be present within the chamber of the system 400 (e.g., on an interior surface or wall), however, due to the system 400 being a vacuum environment during use, heating the chamber air/environment may not be practical. Although not shown in the figure, the substrate assembly 408 may include gas outlets through the support surface to provide heated gas to the substrate 418.

In this chuck 430, the power supply 440 is a bipolar, dual power source having isolated outputs from two power sources 442, 444 at opposite voltages. The power supply 440, particularly the power sources 442, 444, are DC power sources that are not grounded in this design, but are isolated. In some embodiments, the isolated outputs may be referred to as floating.

In one example, the power sources 442, 444 provide equal, offsetting voltages; for example, one power source 442 provides −425V and the other power source 444 provides +425, or vice versa. In other examples, the offsetting voltages are not equal, but either the negative or positive voltage is greater than the other. Either of the power supplies could be set to 0V.

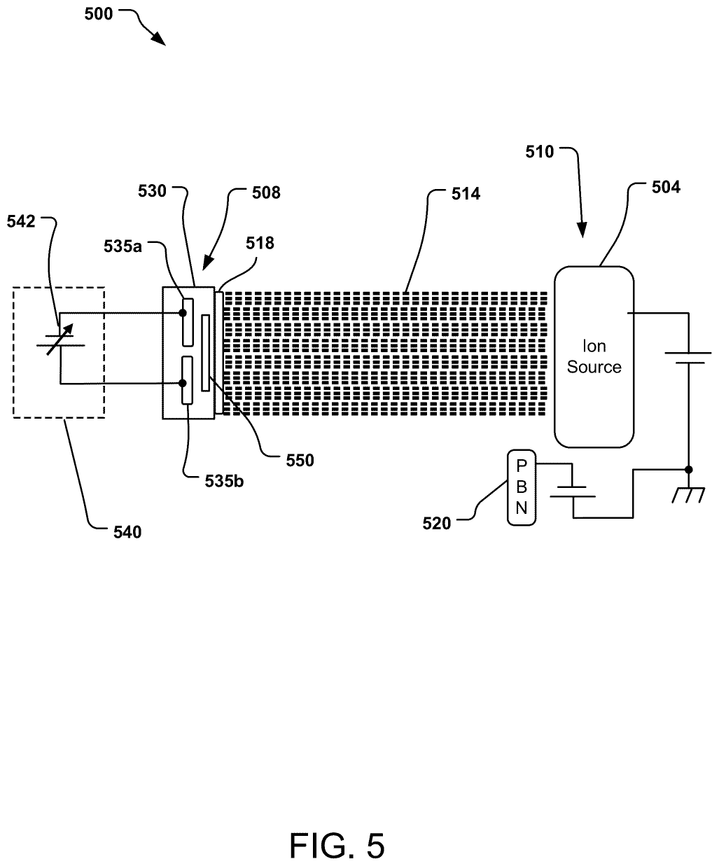

In FIG. 5, a system 500 is shown having an ion beam deposition assembly 510 that includes an ion source 504 and a PBN 520. Each of the ion source 504 and the PBN 520 has a power source (not numbered) which are grounded; although shown connected, the sources may be individually grounded. The ion source 504 produces an ion beam 514 aimed toward a semiconductor substrate 518 retained on a substrate assembly 508 that includes an electrostatic chuck 530. The electrostatic chuck 530 has at least two electrodes 535a, 535b embedded therein, and a support surface for receiving the substrate 518 thereon. The electrostatic chuck 530, particularly the electrodes 535, are connected to a high-voltage power supply 540 to provide a current, at a voltage, to the electrodes 535. Also present in the system 500 is a heating element 550 for heating the substrate 518, e.g., to a temperature of at least 250° C., e.g., 250° C.-650° C.

In this chuck 530, the power supply 540 has a single power source 542 having isolated outputs. The power supply 540, particularly the power source 542, is monopolar and is not grounded in this design.

In one example, the power sources 542 provides a negative voltage; in a specific example, the power source 542 provides −600V.

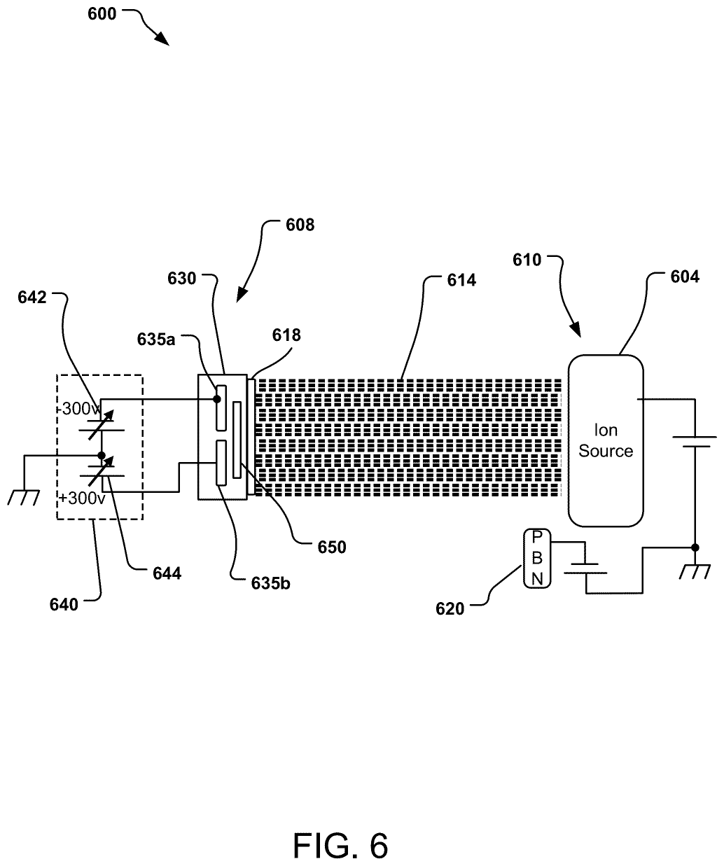

In FIG. 6, another system 600 is shown having an ion beam deposition assembly 610 that includes an ion source 604 and a PBN 620. Each of the ion source 604 and the PBN 620 has a power source (not numbered) which are grounded; although shown connected, the sources may be individually grounded. The ion source 604 produces an ion beam 614 aimed toward a semiconductor substrate 618 retained on a substrate assembly 608 that includes an electrostatic chuck 630. The electrostatic chuck 630 has at least two electrodes 635a, 635b embedded therein, and a support surface for receiving the substrate 618 thereon. The electrostatic chuck 630, particularly the electrodes 635, are connected to a high-voltage power supply 640 to provide a current, at a voltage, to the electrodes 635. Also present in the system 600 is a heating element 650 for heating the substrate 618, e.g., to a temperature of at least 250° C., e.g., 250° C.-650° C.

In this chuck 630, the power supply 640 has dual DC power sources 642, 644 with a central tap ground, with isolated outputs that are used to power both electrodes 635.

In one example, the power sources 643, 644 provide opposite, equal voltages, such as −300V and +300V. In other examples, the two voltages may be unequal.

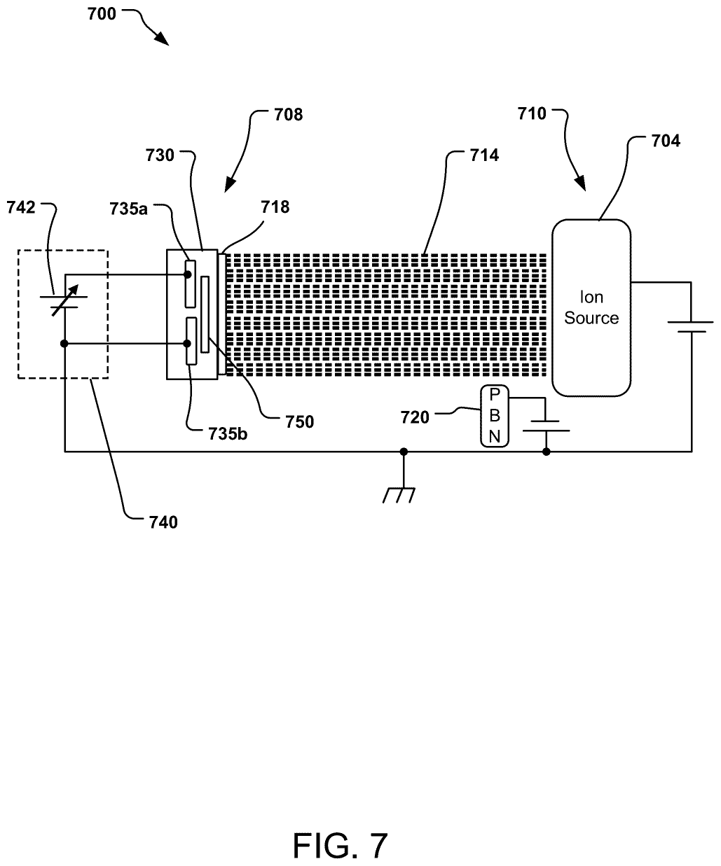

In FIG. 7, another system 700 is shown having an ion beam deposition assembly 710 that includes an ion source 704 and a PBN 720. Each of the ion source 704 and the PBN 720 has a power source (not numbered) which are grounded; although shown connected, the sources may be individually grounded. The ion source 704 produces an ion beam 714 aimed toward a semiconductor substrate 718 retained on a substrate assembly 708 that includes an electrostatic chuck 730. The electrostatic chuck 730 has at least two electrodes 735a, 735b embedded therein, and a support surface for receiving the substrate 718 thereon. The electrostatic chuck 730, particularly the electrodes 735, are connected to a high-voltage power supply 740 to provide a current, at a voltage, to the electrodes 735. Also present in the system 700 is a heating element 750 for heating the substrate 718, e.g., to a temperature of at least 250° C., e.g., 250° C.-650° C.

In this chuck 730, the power supply 740 has a single or monopolar power source 742 that has a negative grounded outlet and a single or monopolar outlet. The electrode 735a is powered positively and the other electrode 735b is grounded through the negative side of the power source 742. The power supply 740, particularly the power source 742, is grounded in this design; in the figure, the power source 742 is connected to the ground of the ion source 704 and the PBN 720, although any could be grounded individually.

In one example, the power source 742 provides a positive voltage differential; in a specific example, the power source 742 provides +850V.

Thus, multiple examples and embodiments of electrostatic chucks have been provided in FIGS. 4 through 7, described above. It is to be understood that any features or details of one design may be utilized for or with any other design, unless contrary to the process, construction or configuration.

Although specific examples of voltages have been provided (e.g., −425V and +425V for FIG. 4, −600V for FIG. 5, 300V and +300V for FIG. 6, and +850V for FIG. 7) other voltages can be used for every and any of the chucks described.

Typically for bipolar voltage sources, if the voltage is different for the two sources (e.g., +300V and −425V), the negative voltage is greater.

The nominal voltage, for any power source, is at least 150V (+150V or −150V), in other embodiments at least 325V. The total voltage differential, whether for a monopolar source or across multiple power sources, is at least 300V, in some embodiments, at least 650V. In some embodiments, the voltage differential is 450V-1000V, in other embodiments 550V-850V.

The electrostatic chucks described above can all be used in any process under any conditions; the chucks are, however, especially configured to be used at elevated temperature, i.e., at least at 250° C., e.g., at 250° C.-650° C. Typically at these temperatures, ceramic materials are used as the support surface.

However, at these temperatures, ceramic materials tend to be leaky dielectrics, requiring higher currents for the high voltages needed to obtain the electrostatic engaging force in the electrostatic chuck. In general, the chucks described herein, when operating at elevated temperature, utilize 100×-1000× more current than a chuck operating at room temperature. Thus, the power supply (e.g., the power supply 440, 540, 640, 740, and variation thereof) is capable of providing high current, measured in milliAmps, to provide the voltage levels needed. The current needed for the electrostatic chucks of these designs is at least 1 milliAmp, and no more than 100 milliAmps, in some embodiments no more than 60 milliAmps, and in other embodiment no more than 30 milliAmps. The power supply may be a commercially available power supply or one that is custom made.

Additionally because of the high voltage needed due to the elevated temperature, the support plate for the substrate (e.g., the support surface 320 of FIG. 3) includes a high temperature electrically insulative or dielectric material, such as a high temperature ceramic, particularly if the heating element of the system is incorporated into the substrate assembly, e.g., so that the backside of the substrate is heated. The entire engagement plate or merely the surface may be the high temperature material.

Examples of suitable high temperature ceramics include carbides, nitrides, oxides, and borides of metals, e.g., transition metals; specific examples include aluminum nitride, boron nitride, silicon nitride, hafnium nitride, and hafnium carbide. The ceramic material may be doped to adjust the electrical conductivity properties of the material.

The electrostatic chucks described herein (e.g., chucks 430, 530, 630, 730, and variations thereof) are particularly conducive for elevated temperature ion deposition process.

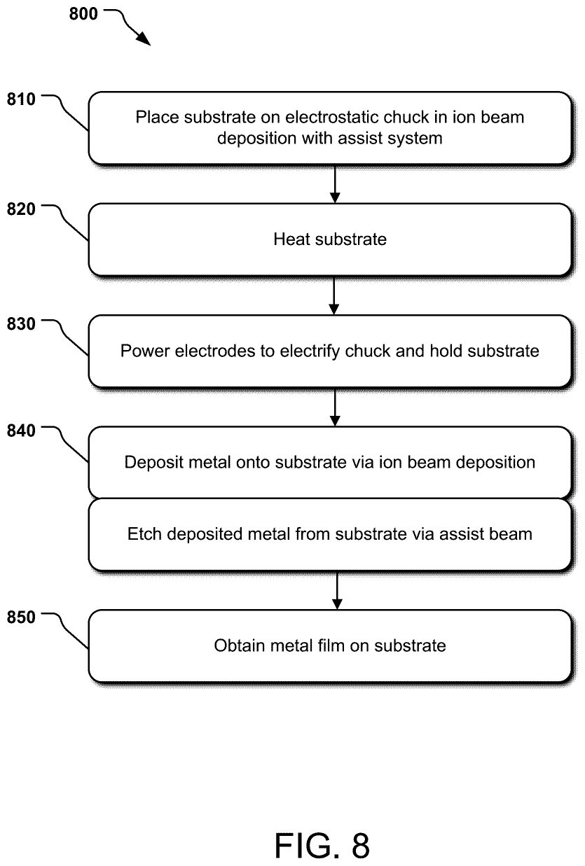

Turning to FIG. 8, an example method 800 for forming a thin layer metal film, such as ruthenium, is described.

In a first step 810, a semiconductor wafer substrate is placed on an engagement plate of an electrostatic chuck in an ion beam deposition with assist system. The engagement plate may be, for example, aluminum nitride. The substrate is heated in a step 820 to at least 250° C. Power is supplied to electrodes in the chuck in step 830 to produce a voltage differential of at least 300V, the power being supplied by a current of at least 1 milliAmp and less than 100 milliAmps. Due to the electrified chuck, an opposite charge forms in the wafer, thus attracting and adhering the wafer to the chuck. In a next step 840, a metal is deposited onto the substrate via ion beam deposition and, at least partially simultaneously, metal is etched from the substrate via assist beam, providing a net deposition rate.

The resulting metal film obtain in step 850 may be a thin layer (e.g., no more than 50 nm), low resistivity, pure (e.g., at least 99%), dense (e.g., at least 99% of theoretical density) film. If a ruthenium target is used in the system, the film with be a ruthenium film.

From the foregoing, it will be appreciated that specific embodiments of the invention have been described herein for purposes of illustration, but that various modifications may be made without deviating from the scope of the invention. Accordingly, the invention is not limited except as by the appended claims.

Although the technology has been described in language that is specific to certain structures and materials, it is to be understood that the invention defined in the appended claims is not necessarily limited to the specific structures and materials described. Rather, the specific aspects are described as forms of implementing the claimed invention. Because many embodiments of the invention can be practiced without departing from the spirit and scope of the invention, the invention resides in the claims hereinafter appended.

Various features and details have been provided in the multiple designs described above. It is to be understood that any features or details of one design may be utilized for or with any other design, unless contrary to the process, construction or configuration. Any variations may be made. For example, processing time, pressure, temperature, etc. may be varied.

The above specification and examples provide a complete description of the structure and use of exemplary implementations of the invention. The above description provides specific implementations. It is to be understood that other implementations are contemplated and may be made without departing from the scope or spirit of the present disclosure. The above detailed description, therefore, is not to be taken in a limiting sense. While the present disclosure is not so limited, an appreciation of various aspects of the disclosure will be gained through a discussion of the examples provided.

Unless otherwise indicated, all numbers expressing feature sizes, amounts, and physical properties are to be understood as being modified by the term “about,” whether or not the term “about” is immediately present. Accordingly, unless indicated to the contrary, the numerical parameters set forth are approximations that can vary depending upon the desired properties sought to be obtained by those skilled in the art utilizing the teachings disclosed herein.

As used herein, the singular forms “a”, “an”, and “the” encompass implementations having plural referents, unless the content clearly dictates otherwise. As used in this specification and the appended claims, the term “or” is generally employed in its sense including “and/or” unless the content clearly dictates otherwise.

Spatially related terms, including but not limited to, “bottom,” “lower”, “top”, “upper”, “beneath”, “below”, “above”, “on top”, “on,” etc., if used herein, are utilized for ease of description to describe spatial relationships of an element(s) to another. Such spatially related terms encompass different orientations of the device in addition to the particular orientations depicted in the figures and described herein. For example, if a structure depicted in the figures is turned over or flipped over, portions previously described as below or beneath other elements would then be above or over those other elements.

What is claimed is:

1. An electrostatic chuck for holding a substrate, the chuck comprising:
a support assembly having two electrodes therein and an electrically insulating support surface for receiving the substrate;
a heating element operably connected to the support surface; and
a high current, high voltage power supply adapted to provide a voltage differential of at least 300V and having two outlets operably connected to the electrodes, with each of the power supply outlets isolated or floating with respect to ground.

2. The electrostatic chuck of claim 1, wherein the high current, high voltage power supply is configured to provide 1 to 100 milliAmps.

3. The electrostatic chuck of claim 2, wherein the power supply is adapted to provide a nominal voltage of at least +/−150V.

4. The electrostatic chuck of claim 1, wherein the heating element is adapted to heat the substrate to at least 250° C.

5. The electrostatic chuck of claim 1, wherein the power supply is a monopolar power supply.

6. The electrostatic chuck of claim 5, wherein the monopolar power supply provides a negative voltage.

7. The electrostatic chuck of claim 1, wherein the power supply has a first power source providing a positive voltage and a second power source providing a negative voltage.

8. The electrostatic chuck of claim 1, wherein the power supply has a bipolar power source providing a positive voltage and a negative voltage.

9. An electrostatic chuck for holding a substrate, the chuck comprising:
a high current, high voltage power supply adapted to provide a voltage differential of at least 300 for operating the electrostatic chuck, the power supplying having two outlets isolated or floating with respect to ground;
a support assembly with a heating element operably connected to an electrically insulating support surface of the support assembly; and
at least two electrodes within the support assembly and electrically connected to the outlets of the power supply for charging the electrodes to electrostatically hold the substrate to the electrostatic chuck.

10. The electrostatic chuck of claim 9, wherein the high current, high voltage power supply is adapted to provide 1 to 100 milliamps.

11. The electrostatic chuck of claim 10, wherein the power supply is adapted to provide a nominal voltage of at least +/−150V.

12. The electrostatic chuck of claim 9, wherein the heating element is adapted to heat the substrate to at least 250° C.

13. The electrostatic chuck of claim 9, wherein the power supply is a monopolar power supply.

14. The electrostatic chuck of claim 13, wherein the monopolar power supply provides a negative voltage.

15. The electrostatic chuck of claim 9, wherein the power supply has a first power source providing a positive voltage and a second power source providing a negative voltage.

16. The electrostatic chuck of claim 9, wherein the power supply has a bipolar power source providing a positive voltage and a negative voltage.

17. A method of holding a substrate in a process chamber, the method comprising:
providing an electrostatic chuck comprising a support assembly having an electrically insulative support surface in the process chamber, the support assembly having two electrodes therein electrically connected to outlets of a power supply for charging the electrodes, the outlets isolated or floating with respect to ground;
placing a substrate on the support surface; and
applying a current of at least 1 milliAmp via the power supply to the at least two electrodes to produce a voltage differential of at least 300V.

18. The method of claim 17, further comprising:
heating the substrate to at least 250° C.

19. The method of clam 17, wherein applying a current of at least 1 milliAmp comprises applying a current of 1 milliAmp to 100 milliAmp.
